(19) United States
(12) Patent Application Publication
(10) Pub. No.: US 2006/0028212 A1
(43) Pub. Date: Feb. 9, 2006

(54) System and method for graphically grouping electrical devices

(76) Inventors: J.P. Steiner, Royersford, PA (US); Frank Fabian JR., Kintnersville, PA (US); Michael Ratushny, Fremansburg, PA (US)

Correspondence Address: OSTROLENK, FABER, GERB & SOFFEN, LLP, 1180 Avenue of the Americas, New York, NY, 10036-8403, US

(21) Appl. No.: 10/913,686

(22) Filed: Aug. 6, 2004

(51) Int. Cl. G01R 31/08

(52) U.S. Cl. 324/527

(57) ABSTRACT

A convenient and intuitive software development environment for graphically grouping together groups of electrical/electronic devices and providing substantially real-time control of graphically selected groups of electrical/electronic devices and systems. In addition to substantially real-time control of a graphically selected group of electrical/electronic devices, users of the present invention can schedule commands to be executed for a group of graphically selected electrical/electronic devices, or command a group of graphically selected electrical/electronic devices to respond to a particular condition.

### BACKGROUND OF THE INVENTION

1. Field of the Invention

The present invention relates generally to automated hardware and software systems, and, more particularly, to systems for selectively controlling a plurality of electrical/electronic devices as a group.

2. Description of the Related Art

Remote control and monitoring of electrical/electronic devices, such as lighting control systems, is known. For example the Digital Addressable Lighting Interface (“DALI”) provides digital addressing of lighting control systems, and can be used to adjust a load, such as to control the luminance of a light, over a communication network. Using DALI, each lighting fixture has its own individual digital address, for example, thus enabling remote communication with the fixture. Accordingly, lights can be switched on and off by commands issued by a remote console. A central controller processes the commands and issues commands in response to control the light fixture.

In spite of the convenience provided by remote control and monitoring systems, such as provided by DALI, groups of electrical/electronic devices that may be physically located far from each other or are otherwise disparate devices are difficult to assign and address. For example, to control various devices to operate as a group, each device having its own individual digital address must be individually selected and assigned to the group, typically by referencing a table of devices and/or zones. When faced with a massive list of thousands of individual electrical/electronic devices, the task associated with defining various groups of individual devices is daunting.

For example, a new exhibition space may contain fifty columns by fifty rows of lighting fixtures. End users may wish to control patterns of the fixtures, for example, to control an overall percentage of light provided thereby. For example, one desired lighting pattern may include the front two rows, the middle five rows, and the last three rows of the lights. Alternatively, a user may desire to light various percentages (e.g., 25%, 50%, and 75%) of the total exhibition space. Moreover, a user may desire to switch some lights on even though those lights are not part of a predefined pattern.

Furthermore some lights may take a long time to strike on. In the interest of providing light to a percentage of a space, such as the exhibition space in the preceding paragraph, one result may be temporary moments of darkness until lights strike on. Alternatively, waste may result because lights will be intentionally left on in order to avoid problems associated with a long strike time.

In the prior art, defining groups of fixtures to provide lighting in accordance with the preceding paragraphs can take a substantial amount of time. For example, each of the individual fixtures is identified by name or number in a table, and must be located by a user in order to add the fixture to a group. Further, a plurality of individual lighting fixtures may be assigned to respective zones. Accordingly, a user must navigate through a large table of many zones, each representing a plurality of lighting fixtures, in order to define groups of lights for various patterns, such as described above. Such a table of zones is not intuitive, and tasks associated with defining various lighting patterns based upon hundreds or even thousands of zones, many of which may include several or many lighting fixtures, is problematic.

### SUMMARY OF THE INVENTION

There is a need in the industry for a user interface for grouping objects that control electrical/electronic devices. More particularly, it is desirable to provide a user interface enabling a selective grouping of two or more graphic icons that function to control or monitor electrical/electronic devices substantially in real time.

There is further a need in the industry for a convenient development environment for developing custom user interfaces that provide substantially real-time control of selected groups of electrical/electronic devices and systems.

There is further a need for substantially real-time control over a group of electrical/electronic devices such that users can issue or schedule commands to be executed for a group of electrical/electronic devices, or command a group of electrical/electronic devices to respond to a particular condition.

In a preferred embodiment, the present invention provides a system for developing a user interface for controlling a group of one or more devices. The system includes a design module provided by an information processor and operative to represent a physical location. The design module is further operative to represent the devices that are installed in the physical location. Further, the present invention includes a draw module that graphically associates the devices with a group. Moreover, the present invention includes a run time module that provides the user interface to a workstation. The design module operates to associate at least one command with the group, and the devices perform at least one respective function in accordance with the command. Furthermore, the run time module provides the user interface to control the group based on the at least one command.

In an alternative embodiment, the present invention provides a system for electrically controlling a plurality of devices which are arrangeable in device group(s). In this embodiment, an information processor operates to store a plurality of graphic symbols, and each of the graphic symbols represents a respective one of the devices. Further, each graphic symbol is operative to electrically control its respective device. A module provided by the information processor is operative to define the device group(s) in response to a user selection of the graphic symbols. Another module, also provided by the information processor, is operative to electrically control the group. In this embodiment, for example, a user selects a symbol (e.g., by clicking on the symbol) representing the group, and in response to the user selection, the command module issues a command to the group. Other features and advantages of the present invention are described in detail below.

### BRIEF DESCRIPTION OF THE DRAWINGS

For the purposes of illustrating the invention, there is shown in the drawings a form which is presently preferred, it being understood, however, that the invention is not limited to the precise arrangements and instrumentalities shown. The features and advantages of the present invention will become apparent from the following description of the invention that refers to the accompanying drawings, in which:

FIG. 1 shows an example hardware arrangement illustrating an embodiment of the present invention for developing user interfaces to monitor and control groups of electrical/electronic devices;

FIG. 2 illustrates functional elements associated with the information processor of FIG. 1;

FIG. 3 is a block diagram that illustrates one or more software modules that contribute features to enable remote monitoring and control of groups of electrical/electronic devices;

FIG. 4 illustrates an example display screen provided by a software design module that shows a virtual representation of a hotel conference center;

FIG. 5 is a diagram showing an example multi-processor network that includes a control processor and a network interface for monitoring and controlling groups of electrical/electronic devices;

FIG. 6A shows an example display screen that is provided to a user operating a software design module in accordance with a preferred embodiment of the present invention;

FIG. 6B shows an example navigation pane of a display screen that illustrates a plurality of spaces added to a display screen provided by the software design module;

FIG. 7A shows an example display screen that is provided to a user operating a software draw module in accordance with a preferred embodiment of the present invention;

FIG. 7B shows an example library pane of a display screen of the draw module of FIG. 7A;

FIGS. 8A-8G show example panes of display screens during varying stages in which the steps of grouping electrical/electronic devices in accordance with a preferred embodiment of the present invention are executed;

FIG. 9 shows an example display screen that is provided to control a group of electrical/electronic devices substantially in real time via a run time software module; and

FIG. 10 is a flow chart illustrating steps associated with defining groups of electrical/electronic devices in accordance with a preferred embodiment of the present invention.

### DETAILED DESCRIPTION OF EMBODIMENTS OF THE INVENTION

In a preferred embodiment, the present invention provides a convenient and intuitive software development environment for developing custom user interfaces that provide substantially real-time control of groups of electrical/electronic devices and systems. In addition to providing substantially real-time control of electrical/electronic devices, users of the present invention can schedule commands to be executed for a group of electrical/electronic devices, or command a group of electrical/electronic devices to respond to a particular condition.

In a preferred embodiment, the custom user interfaces operate across a communication network and provide a user with a virtual representation of a physical environment, such as a room, a floor of a building, or an outdoor facility (e.g., a stadium, shopping center, parking lot, etc.). Any physical environment that includes a plurality of electrical/electronic devices can be virtually represented in accordance with the present invention. Further, the user interfaces provide substantially real-time monitoring and control over a group of electrical/electronic devices, including, for example, a mixture of lighting fixtures, window treatments, wall controls, communication devices, audio/visual devices, heating, ventilating, air-conditioning and refrigeration products that are located in the physical environment represented by the present invention.

The present invention preferably employs networking and communication interfaces, such as network interface cards (NIC) and control processors to address and control specific electrical/electronic devices installed in various locations. The networking and communication interfaces enable control over groups of potentially different kinds of devices over a communication network. One skilled in the art will recognize that any kind of network interface is envisioned herein. The examples and embodiments which includes NICs are not meant to limit the present invention thereto. For example, processors may have an integrated network interface, such as an Ethernet port, and built directly into a port.

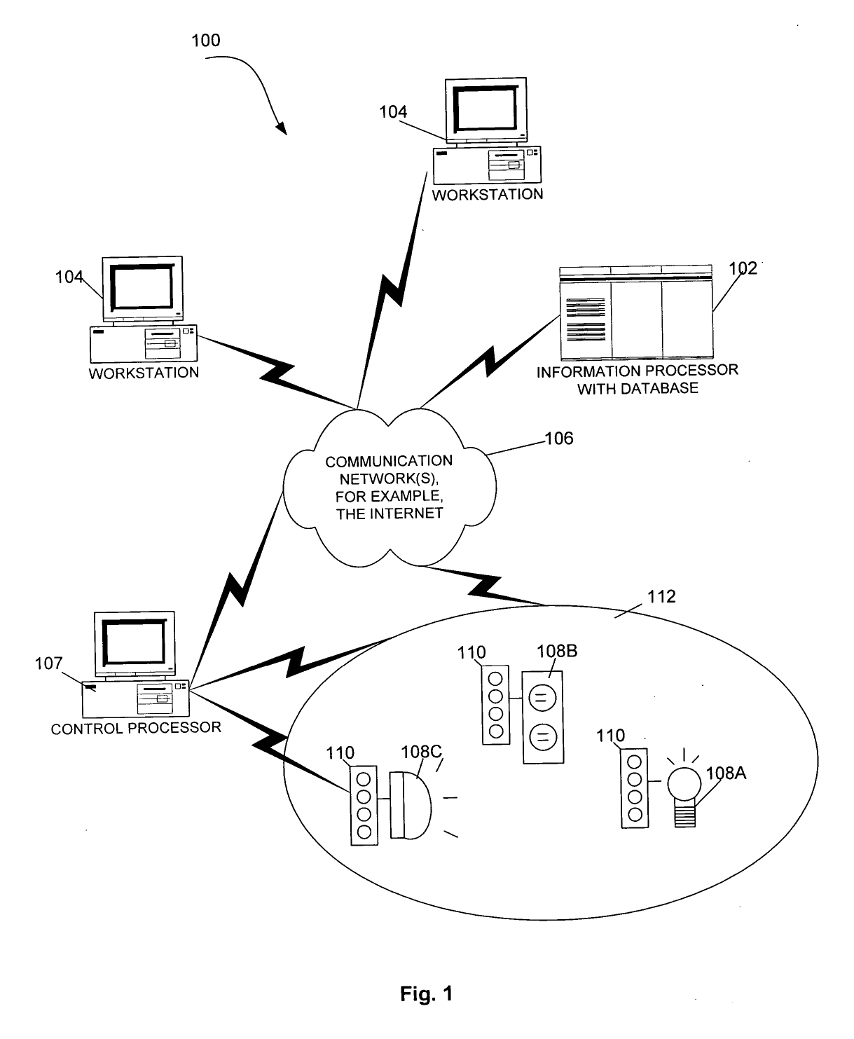

Referring to the drawings, in which like reference numerals refer to like elements, FIG. 1 shows an example preferred embodiment of the present invention, including a hardware arrangement for developing user interfaces to monitor and control groups of electrical/electronic devices, and referred to generally as system 100. System 100 comprises at least one information processor 102, at least one workstation 104 and at least one control processor 107, each of which is adapted to communicate over communication network 106. The information processor 102 preferably provides an Internet web site that includes a database and user interface for users of workstations 104. In a preferred embodiment, electrical/electronic devices 108 are electronically connected to addressable power panels 1 10 that interface with control processors 107 to receive commands. Thus, commands are issued through communication network 106 to control the behavior of electrical/electronic devices 108.

In the embodiment shown in FIG. 1, electrical/electronic device 108A represents a lighting fixture, electrical/electronic device 108B represents an HVAC system, and electrical/electronic device 108C represents an audio system. Furthermore, electrical/electronic devices 108A, 108B and 108C are shown grouped as electrical/electronic device group 112, and can be controlled to perform various operations as a group. Thus, the present invention provides for remote monitoring and control group of a diverse range of electrical/electronic devices 108.

Information processor 102 preferably includes databases necessary to support the present invention. However, it is contemplated that information processor 102 can access any required database via communication network 106 or any other communication network to which information processor 102 may be coupled. Communication network 106 is preferably a global public communication network such as the Internet, but can also be a wide area network (WAN), local area network (LAN), or other network that enables two or more computers to communicate with each other.

Although the communication network 106 is represented in FIG. 1 as a single communication network, the invention is not so limited. It is envisioned herein that communication network 106 can comprise one or more networks, including, a wide area network, a local area network, a global communication network and the like.

Preferably, information processor 102, workstation 104 and control processors 107 are capable of sending and receiving data across communication network 106, e.g., mainframe computers, mini computers, personal computers, laptop computers, a personal digital assistants (PDA) and Internet access systems such as Web enabled telephones. In addition, information processors 102 and workstations 104 are preferably equipped with a web browser, such as MICROSOFT INTERNET EXPLORER, NETSCAPE NAVIGATOR and the like. Information processors 102 and workstations 104 are coupled to communication network 106 using any known data communication networking technology.

Control processors 107 are preferably adapted to provide control of electrical/electronic devices, such as the GRAFIK 7000 processor offered for sale by the assignee of the present patent application. As known by those skilled in the art, the GRAFIK 7000 processor is capable of controlling loads for many kinds of zones, for example, DMX zones, motor zones, ceiling fans, shades, or the like. In accordance with the present invention, zones are controlled by dropping icons representing switch legs onto a virtual power panel (displayed in a software application) as a holder for the switch legs. Using network interface devices and control processors 107, most power panels can be controlled in accordance with the present invention.

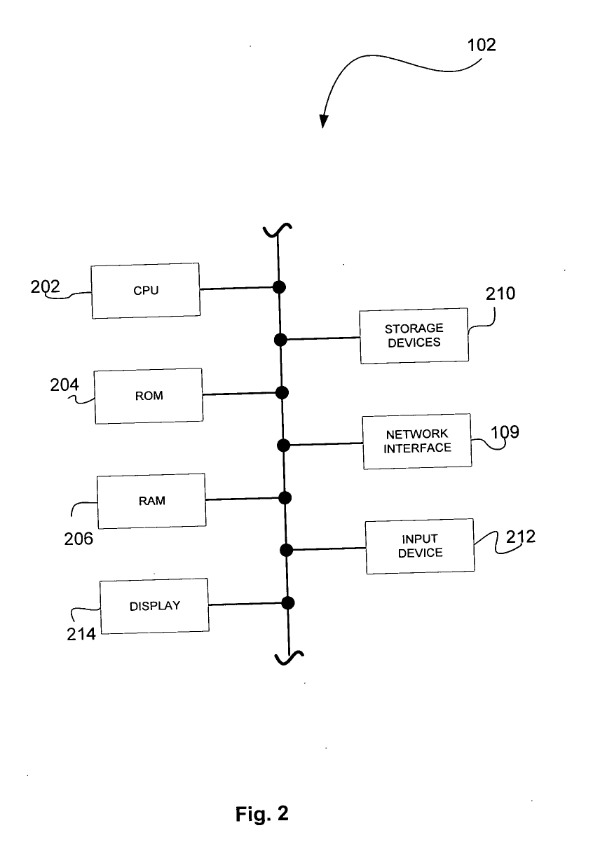

As shown in FIG. 2, the functional elements of information processor 102 include one or more central processing units (CPU) 202 used to execute software code and control the operation of information processor 102, read-only memory (ROM) 204, random access memory (RAM) 206, one or more network interfaces 109 to transmit and receive data to and from other computers across a communication network, storage devices 210 such as a hard disk drive, floppy disk drive, tape drive, CD ROM or DVD for storing program code databases and application data, one or more input devices 212 such as a keyboard, mouse, track ball, microphone and the like, and a display 214.

The various components of information processor 102 need not be physically contained within the same chassis or even located in a single location. For example, storage device 210 may be located at a site which is remote from the remaining elements of information processor 102, and may even be connected to CPU 202 across communication network 106 via network interface 109. Information processor 102 preferably includes a memory equipped with sufficient storage to provide the necessary databases, forums, and other community services as well as acting as a web server for communicating hypertext markup language (HTML), XML, Java applets, Active-X control programs or the like to workstations 104. Information processors 102 are arranged with components, for example, those shown in FIG. 2, suitable for the expected operating environment of information processor 102. The CPU(s) 202, network interface(s) 109 and memory and storage devices 210 are selected to ensure that capacities are arranged to accommodate expected demand.

The functional elements of information processor 102 shown in FIG. 2 are of the same categories of functional elements present in workstations 104 and control processors 107. However, not all elements need be present in workstations 104 or control processor 107. For example, storage devices, in the case of PDAs, and the capacities of the various elements are arranged to accommodate the expected user demand. For example, CPU 202 in workstation 104 may be a smaller capacity CPU than the CPU present in information processor 102. Similarly, it is likely that information processor 102 will include storage devices of a much higher capacity than storage devices present in workstation 104. Of course, one of ordinary skill in the art will understand that the capabilities of the functional elements can be adjusted as needed.

One skilled in the art of writing computer executable code (i.e., software) can implement the functions described herein using one or more of a combination of popular computer programming languages and development environments including, but not limited to, C, C++, C#, Visual Basic, JAVA, HTML, XML, ACTIVE SERVER PAGES, JAVA server pages, servlets, and a plurality of web site development applications.

Although the present invention is described by way of example herein and in terms of a web-based system using web browsers and a web site server (e.g., information processor 102), system 100 is not limited to such a configuration. It is contemplated that system 100 is arranged such that workstation 104 communicates with and displays data received from information processor 102 using any known communication and display method, for example, using a non-Internet browser WINDOWS viewer coupled with a local area network protocol such as the Internet Packet Exchange (IPX), dial-up, third-party, private network or a value added network (VAN).

It is further contemplated that any suitable operating system can be used on information processor 102 and workstation 104, for example, DOS, WINDOWS 3.x, WINDOWS 95, WINDOWS 98, WINDOWS NT, WINDOWS 2000, WINDOWS ME, WINDOWS CE, WINDOWS POCKET PC, WINDOWS XP, MAC OS, UNIX, LINUX, PALM OS, POCKET PC and any other suitable operating system.

As used herein, references to displaying data on information processor 102 workstation 104, and control processor 107 regard the process of communicating data across communication network 106 and processing the data such that the data is viewed on a display 214, for example by using a web browser and the like. As is common with web browsing software, the display 214 on workstation 104 presents sites within the system 100 such that a user can proceed from site to site within the system by selecting a desired link.

Therefore, each user's experience with system 100 is based on the order with which he/she progresses through the display screens. Graphic controls are preferably available in the display screens and modules to initiate data processes, and to provide convenient navigation between the display screens and modules of system 100. In other words, because the system is not completely hierarchical in its arrangement of display screens, users can proceed from area to area without the need to “backtrack” through a series of display screens. For that reason, and unless explicitly stated otherwise, the following discussion is not intended to represent any sequential operation steps, but rather to illustrate the components of system 100.

Terminology

In accordance with the teachings herein, various terminology is used and provided for teaching one skilled in the art how to build and practice the invention. The following list of terms and definitions are intended, generally, to assist one skilled in the art. The definitions provided herein are not meant to limit or restrict the meaning of terms from their ordinary or common meaning, or from definitions of the terms commonly used in the industry.

Address: A unique alphanumeric identifier that is applied to a component in a system communication link.

Astronomic time event: An event defined as a number of seconds before or after sunrise or sunset time.

Base drawing: An image representing a physical location before any symbols or hot spots are added.

Compile: The act of translating user-defined project data into the machine level language that various forms of hardware and software understand.

Conditional: A programming model that may execute different presets based on logical statements that utilize the values of variables or moveable walls.

Control: A feature that allows a user to change the present value of a parameter for an object or collection of objects. This will generate an event in the system.

Control station: One or more ganged control station devices under a common faceplate.

Control station device: A device that provides a point of input or output. In most cases, these are wall-mounted controls with buttons.

Control type: Indicates the manner in which that fixture or switch leg needs to be controlled. Examples included switched and dimmed.

Electrical/electronic device: A device that produces or is powered by electricity. Electronic devices are a subset of electrical devices and include electronic circuits including electronic components such as transistor integrated circuits, capacitors, resistors and inductors for example.

Equipment: The hardware of the system that is installed in an enclosure or is found in a panel. Examples of equipment include processors, interfaces and switch leg controls.

Event: An occurrence that can trigger programming to be executed.

Graphic: A base drawing that contains one or more symbols and/or one or more hot spots.

Group: A named collection of one or more electrical/electronic devices or other groups that share a common functional purpose. This is consistent with the building automation industry standard term.

Hot Spot: A user-defined region on an image that may act as a monitor, control, or navigation point to another graphic.

Hyperlink: A selectable connection from one or more words, pictures or other information objects to others in which the selectable connection is presented within the web browser. The information object can include sound and/or motion video. Selection is typically made by “clicking” on the hyperlink using an input device such as a mouse, track ball, touch screen and the like. Of course, one of ordinary skill in the art will appreciate that any method by which a hyperlink can be selected is sufficient.

Link: The means by which the individual parts of a control system communicate with each other.

Load type: A classification of a load determined by the load's electrical characteristics. The load type determines the manner in which the load can be controlled based on the switch leg control's capability.

Mode: A function and a set of associated values that determine the behavior of a group or other object to which it is applied. This is consistent with the building automation industry standard term.

Monitor: An object that allows the user to view a present value of a parameter for an object or collection of objects.

Object: A generic term that may refer to any product or abstract entity that is added to a project. An example product may be a GP48 dimming panel (offered by the assignee of the present patent application), and an example abstract entity may be a scene.

Panel: A factory built pre-wired assembly of hardware.

Partitionable space: A term that refers to a specific type of space. A partitionable space allows the user to include fixed and moveable walls. These walls can be used to achieve various lighting effects. A partitionable space can contain additional spaces, referred herein, generally, as child spaces.

Preset: A user defined set of one or more objects and their associated commands/levels.

Processor: A piece of hardware that communicates with other hardware via a series of links. The processor is capable of running programming that will alter the states of objects in the system.

Programming: Predetermined behavior that is defined to occur as the result of an event. Programming does not include the event itself.

Programming model: Specifies how a user must interact with a device to execute the defined programming for that device.

Project: A named container that includes all information about a system.

Real-time event: An event defined in terms of the time of day.

Scene: A lighting effect achieved by adjusting one or more zones to various levels.

Schedule: A collection of event/programming pairs.

Single action: A programming model that executes the same preset with for each event.

Software module: One or more discrete components that contribute to the effectiveness of the present invention. Modules can include software elements, including but not limited to functions, algorithms, objects and the like. Modules can also include hardware elements, substantially for performing the steps or contributing to the performance of steps associated with the present invention. Modules can operate independently or, alternatively, can depend upon one or more other modules in order to function.

Space: A generic term that refers to a physical representation of a building, or any of its parts. Spaces can contain other spaces. Additionally, each space can contain other objects. Each object in a space can only be assigned to one space.

Switch leg: A connection between a group of loads and a switch leg control.

Switch leg control: Any electronic device that controls a switch leg by varying the signal delivered to the load(s). In most cases, it is situated between the circuit breaker and the load(s) being controlled. This includes wall box and panel based switch leg controls.

Symbol: A graphical entity that is placed on a drawing typically used to monitor or control the state of an object.

Time clock: A collection of schedules.

Variable: A user created object that can be of three types: True/False, Multi-state, or Integer. Variables can be defined in the design module (described below).

Variable State: The state of a variable. Examples may include: morning, afternoon, or evening.

Wall: A structure that is used to define a partitionable space.

Wall state: A state of a moveable wall. Examples of wall states include fully open, fully closed, half open or the like.

Zone: A collection of one or more devices controlled as one unit (may also be referred to, herein, as a channel).

Zone type: A field that is calculated based on the types of switch legs that are associated with a particular zone.

Networking

As noted above and shown in FIG. 1, the present invention preferably operates over one or more communication networks such that one or more groups of electrical/electronic devices can be monitored and controlled via user interfaces. A description of networking technology used in accordance with an embodiment of the present invention is provided below.

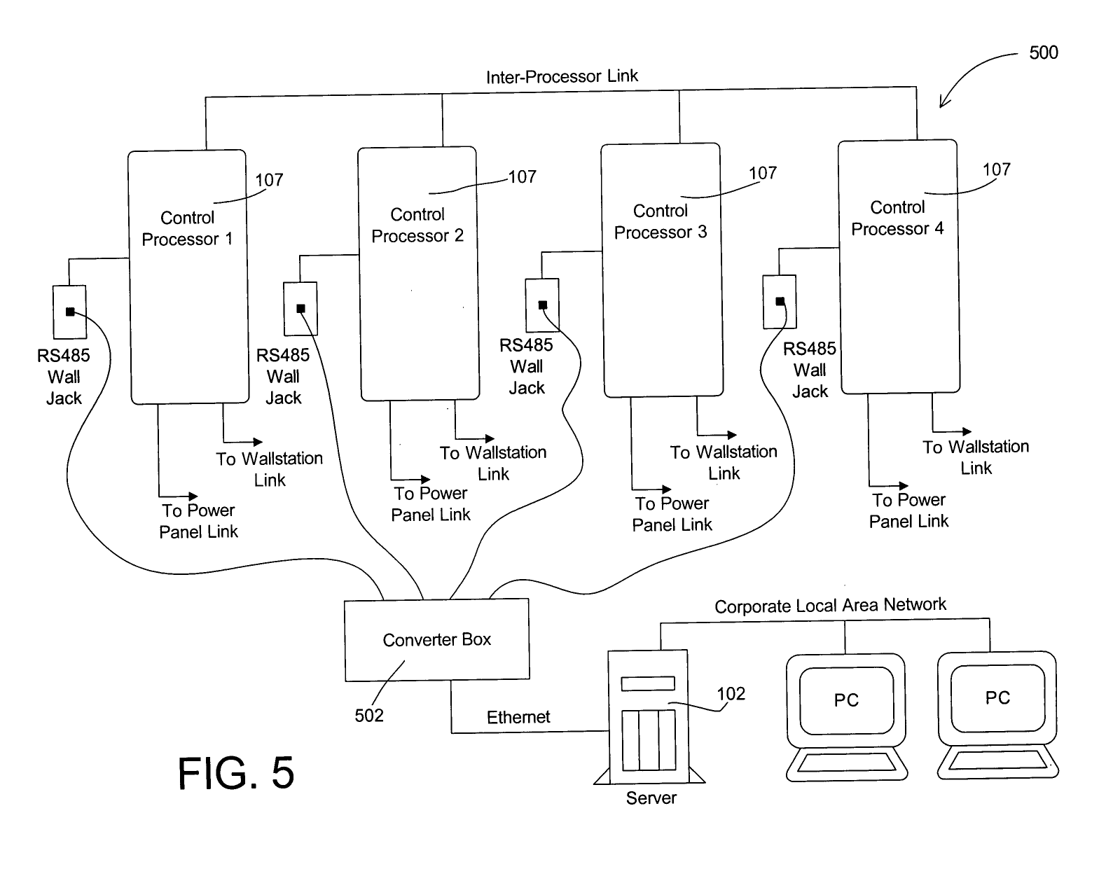

FIG. 5 is a diagram showing a multi-processor network 500 including control processors 107 and a network interface card 109 for monitoring and controlling groups of electrical/electronic devices 108. Electrical/electronic devices 108 are controlled by power panels connected to the power panel links. In a preferred embodiment, one NIC 109 is provided with information processor 102 and an Ethernet port is provided with the converter box 502. Thus, one can communicate to the converter box 502 from the control processor 107 via an Ethernet connection. Preferably, each control processor 107 is provided with two NICs 109, one dedicated to communicating with electrical/electronic device(s) 108 and another NIC 109 which is used to communicate over another communication network, such as provided by a customer, and further to connect to various client computers. Control processor 107 preferably provides the ability to access and modify databases in connection with addressing and controlling electrical/electronic devices 108. Further, processor 107 provides the ability to perform real-time monitoring and controlling capabilities, for example, to create scheduling or to command electrical/electronic devices 108 to behave in particular ways in response to various conditions.

As noted above, NIC 109 allows a computing device to communicate across a network. In a preferred embodiment of the present invention, processor 107 is equipped with two NICs 109. One NIC 109 allows the control processor 107 to communicate with the electrical/electronic devices 108 and the other NIC card allows the control processor 107 to connect to clients on a customer's corporate network and beyond.

Converter box 502 is preferably provided to convert between Ethernet and RS-485. RS-485 is considered more desirable than Ethernet because RS-485 is more cost effective over long distances than Ethernet. For example, a single section of RS-485 can carry a signal up to 2000 feet before a repeater is required, whereas Ethernet requires a repeater roughly every 300 feet. Furthermore, an interprocessor link is employed to allow multiple electrical/electronic devices 108 to communicate to each other using RS-485 communication. This link enables interprocessor time clock events and successful execution of cross processor scripts.

Software Modules

In accordance with one embodiment of the present invention, software modules operate to enable users to develop and use custom user interfaces for monitoring and/or controlling groups of electrical/electronic devices. In an alternative embodiment, users selectively group graphic screen controls that represent a plurality of electrical/electronic devices in order to monitor and/or control the devices substantially in real time. In this alternative embodiment, no separate user interface is required to selectively group graphic controls representing electrical/electronic devices on one hand, and controlling those electrical/electronic devices as a function of the selected group on the other hand.

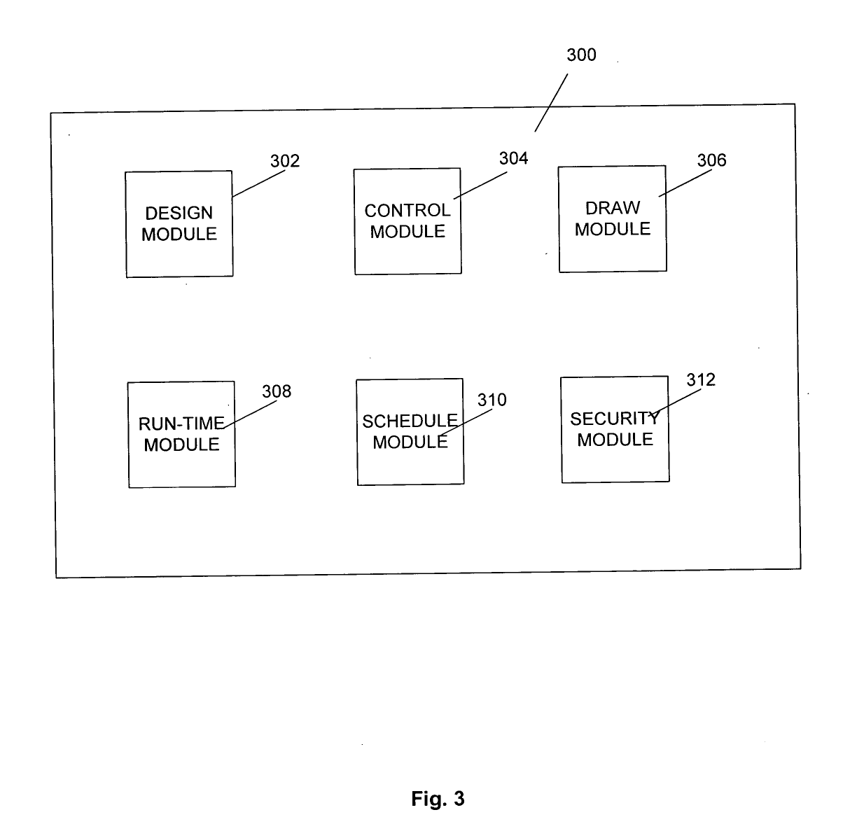

FIG. 3 is a block diagram that illustrates one or more software modules, referred generally as system 300, that contribute features to enable remote monitoring and control of electrical/electronic device groups 112. As shown in FIG. 3, design module 302 (for overall system configuration and programming), control module 304 (for defining the priority of a zone), draw module 306 (a graphical entry tool for configuring custom interfaces for controlling electrical/electronic device groups 112), run time module 308 (for substantially real-time operation of the system), schedule module 310 (for scheduling operations) and security module 312 (for assigning user rights) operate to enable a user to develop and operate custom user interfaces for remote control of electrical/electronic devices 108.

Continuing with a summary of some of the modules provided by the present invention, design module 302 includes a graphical user interface that provides a virtual representation of a physical environment, such as a room, a floor of a building, or an outdoor facility. Design module 302 allows the user to model a facility by adding new spaces, adding zones, creating scenes, programming time clocks and control station devices, and many other features. In a preferred embodiment, design module 302 is not used for real-time control of the system.

For example, design module 302 provides an interface that includes a representation of a physical location, such as a floor of a building. Preferably, graphic screen controls, such as dialogue boxes, buttons, tables, drop-down lists, list boxes, checkboxes, radio buttons or the like, are selected by a user to define and program elements of the physical location represented in design module 302. Examples of electrical/electronic devices 108 represented in design module 302 include lighting control systems, wall units, panels, shades, zones, switches, and processors. Furthermore, a plurality of electrical/electronic devices 108 can be programmed to perform various tasks as a group. In a preferred embodiment of the present invention, design module 302 functions to control a group of electrical/electronic devices 108 to operate, or, alternatively, to prevent operation. Furthermore, electrical/electronic devices 108 can be controlled to operate according to predefined schedules. For example, a group of lighting fixtures can be scheduled to turn off at a certain time, or turn on or off in response to a predefined event, such as an emergency (e.g., a fire or power failure).

When a command is issued to a group of electrical/electronic devices 108, the members of the group respond according to the context of the command and of the device 108 receiving the command. For example, a group of devices 108 including a control station device (keypad) and a zone (dimmers) receive a command to set an intensity level. Such a command would make no sense to the control station device, but makes sense to the zone. In accordance with the present invention, only the zone responds to the command. In another example, a group containing a zone, a time clock and a control station device is defined. A command is issued to disable the group. In this example, the control station device is disabled, the time clock is suspend, and the zone is unaffected. Thus, devices 108 associated with a group respond to or ignore commands as appropriate to the particular context of the command.

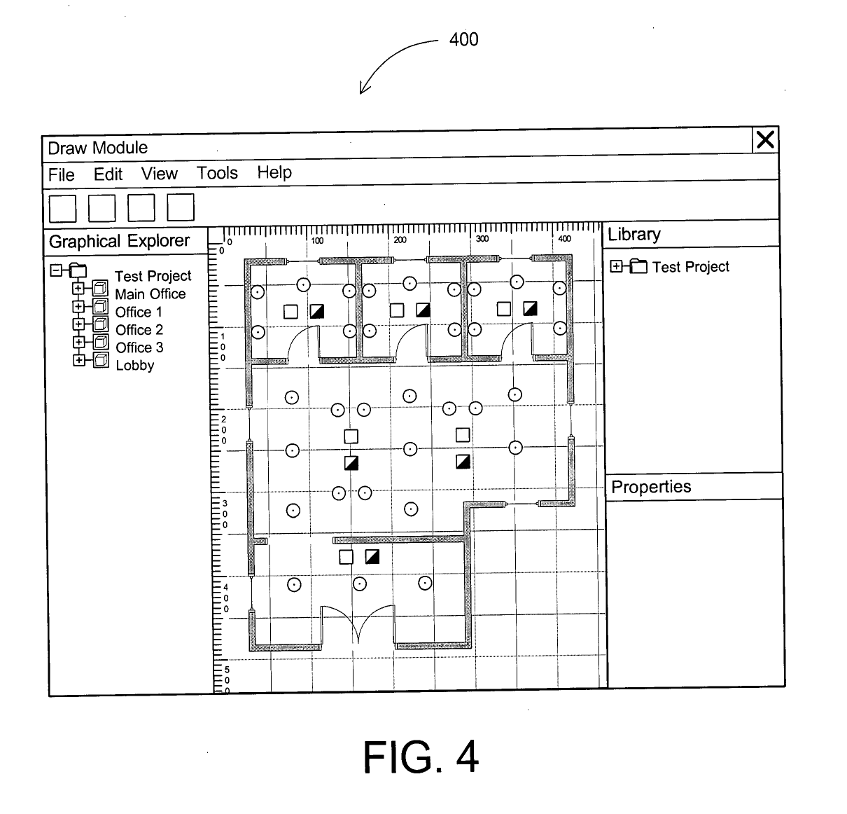

FIG. 4 illustrates an example display screen 400 as provided by draw module 306 that shows a virtual representation of a hotel conference center. Display screen 400 enables the representation of the floor plan of a building such that electrical/electronic devices 108 can be added to the conference center to illustrate locations and to program behavior thereof. Many physical environments that include electrical/electronic devices 108, for example, zones, control stations, control station devices and switch legs, to provide light, sound, and various other features can be represented in display screen 400. Using the present invention, and as described in detail below, a user can select a single graphic button in order to monitor and control a group of electrical/electronic devices 108 substantially in real time.

Design Module

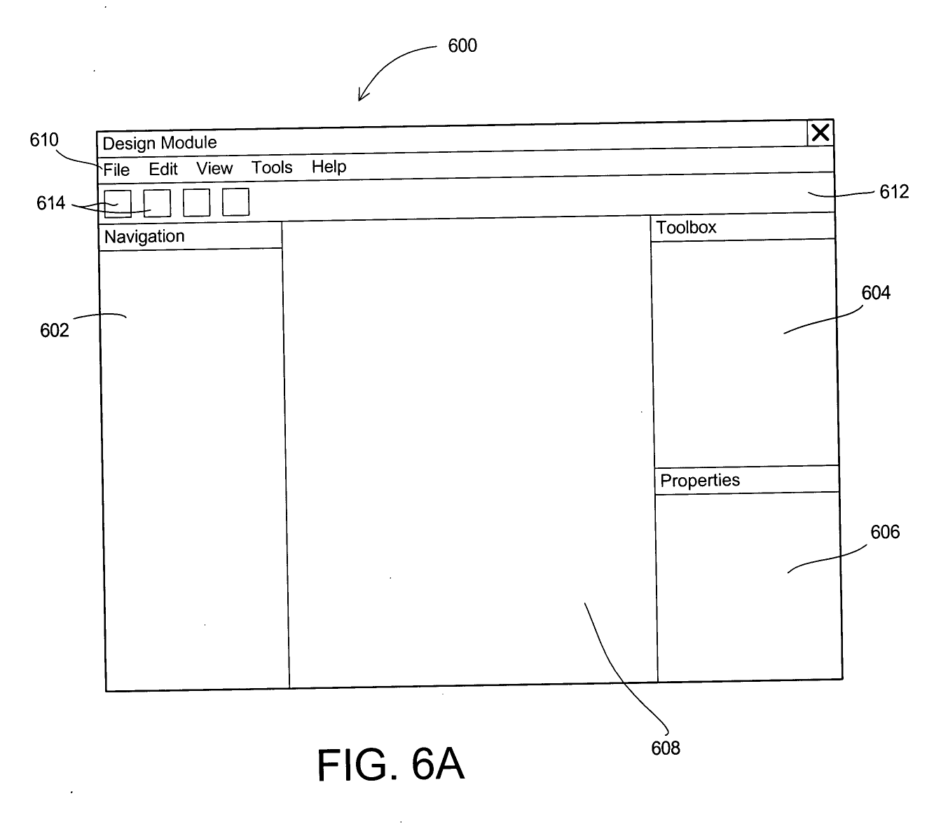

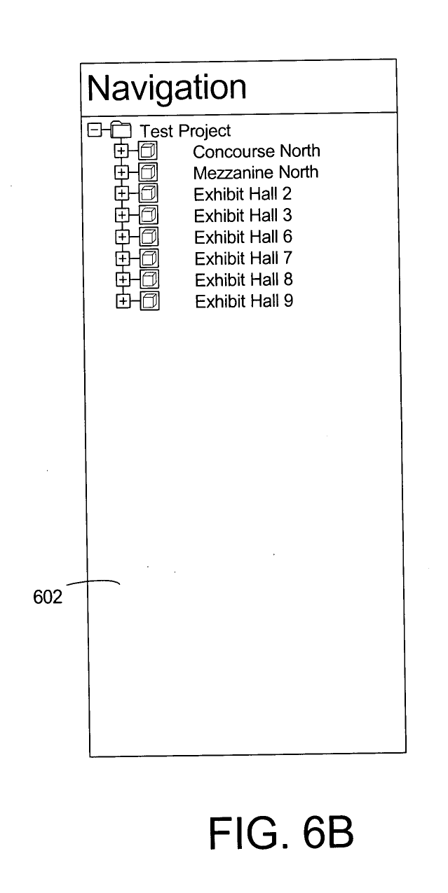

FIG. 6A shows an example display screen 600 that is provided to a user operating design module 302.

A user preferably operates design module 302 to perform various functions such as adding virtual representations of a new space, a new partitionable space, a new control station, a new control station device, a new switch leg, a new zone, a new scene, a new time clock, a data variable or the like. Furthermore, a user can add equipment, panels and switch leg controls via display screen 600. After a physical environment is defined using design module 302, for example, a user addresses any addressable hardware to inform processors 107 which pieces of hardware are connected to it.

For example, and as shown in FIG. 6A, navigation pane 602 (appearing at the left) provides convenient navigation to various elements of a physical location, including spaces, control stations, switch legs, and various electrical/electronic devices 108. Navigation pane 602 is preferably provided to include graphic icons of folders, similar to a file explorer such as provided in MICROSOFT WINDOWS. FIG. 6B shows an example navigation pane 602 that illustrates a plurality of spaces that have been added by a user to the design module 302.

Continuing with example display screen 600, toolbox pane 604 (appearing at the top right) allows a user to add other objects to a system. Further, in the lower right portion of display screen 600, properties pane 606 allows a user to see and modify properties of an object, such as a control station, that is presently selected. In the center portion of display screen 600, main pane 608 displays lists of objects. Objects can be added to spaces displayed in main pane 608 by dragging icons from the toolbox pane 604 and dropping the icons into the main pane 608. Other elements of display screen 600 include menu 610 for performing file, edit and view operations, in addition to customizing design module 302 using various tools, and toolbar 612 with icons 614 for quick access to most display screens provided by design module 302.

Moreover, display screen 600 can be used to program control station devices and time clock schedules. The present invention preferably supports conditional programming (e.g., to control an electrical/electronic device group 112 in response to a certain time of day, temperature or other condition). In a preferred embodiment of the present invention, draw module 306 is used to define groups of electrical/electronic devices 108 and design module 302 is used to supply programming code to control and/or monitor electrical/electronic devices 108 as a group.

By providing a uniform interface for representing physical environments and electrical/electronic devices 108, the present invention provides a convenient way to develop custom user interfaces that control groups of electrical/electronic devices.

Control Module

The present invention provides control module 304 to set the priority of a zone by utilizing programming, for example, previously performed in design module 302. For example, a zone can be locked such that the zone's intensity can not be modified until it is unlocked. Thus, an administrator can use the present invention to restrict modifications to groups of electrical/electronic devices 108, including, for example, zones.

Draw Module

In accordance with the present invention, two or more electrical/electronic devices 108 (which may be physically located in disparate areas or perform different operations) can be grouped to function together. In accordance with a preferred embodiment of the present invention, draw module 306 provides features for developing a user interface to be used, for example, over the Internet and/or other communication network to control electrical/electronic device groups 112. Preferably, digital images in various formats, such as TIFF, JPEG, GIF, BMP or the like, can be imported and placed in a display screen to represent a physical location. For example, an image generated from a CAD system (e.g., AUTOCAD, MICROSTATION, SOLIDWORKS, or INTELLICAD) can be imported into the present invention to display an architectural drawing of a floor of a building. In this way, virtual representations of electrical/electronic devices 108 that are physically installed on the floor represented in the CAD image can be placed within the image. Thus, an accurate representation of electrical/electronic devices 108 can be provided by the present invention.

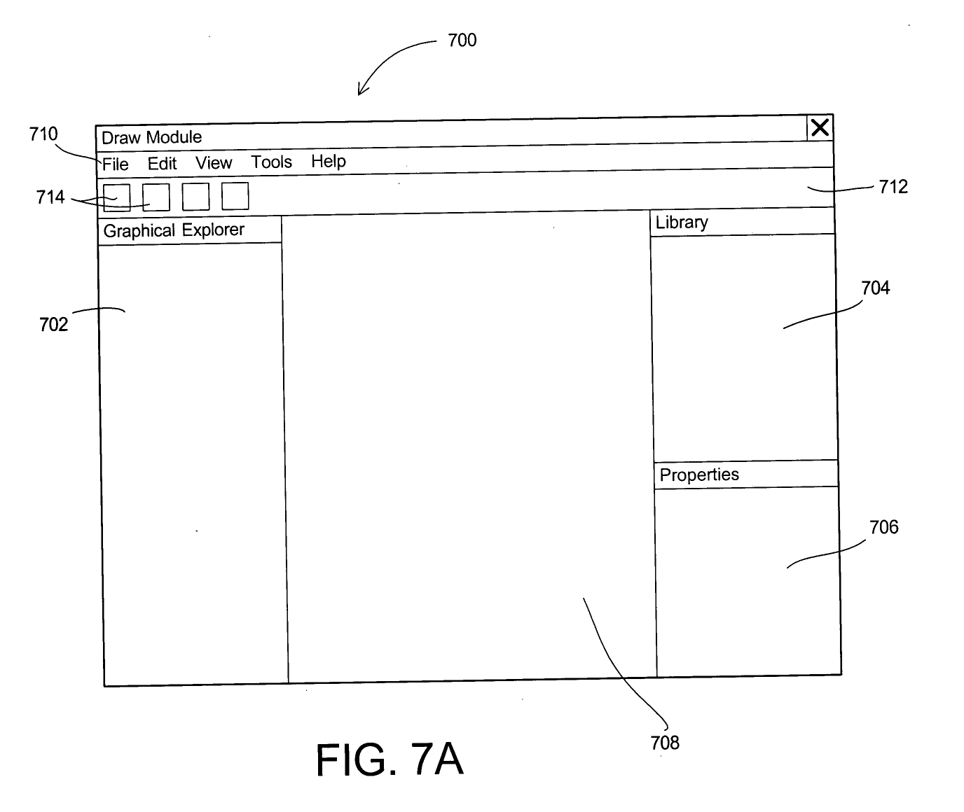

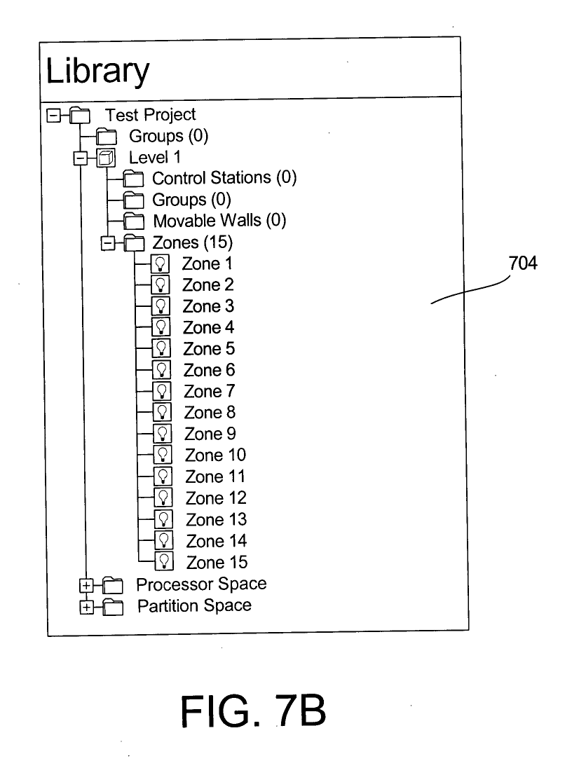

FIG. 7A shows an example display screen 700 that is provided to a user operating draw module 306. Note that display module 302 and draw module 306 provide display screens that share similarities with respect to layout and graphic screen controls. Draw module 306 includes graphical explorer pane 702, library pane 704, properties pane 706, and main pane 708. Display screen 700 also includes menu 710 and toolbar 712 with icons 714. Main pane 708 displays graphic icons representing various electrical/electronic devices 108. FIG. 7B shows an example library pane 704.

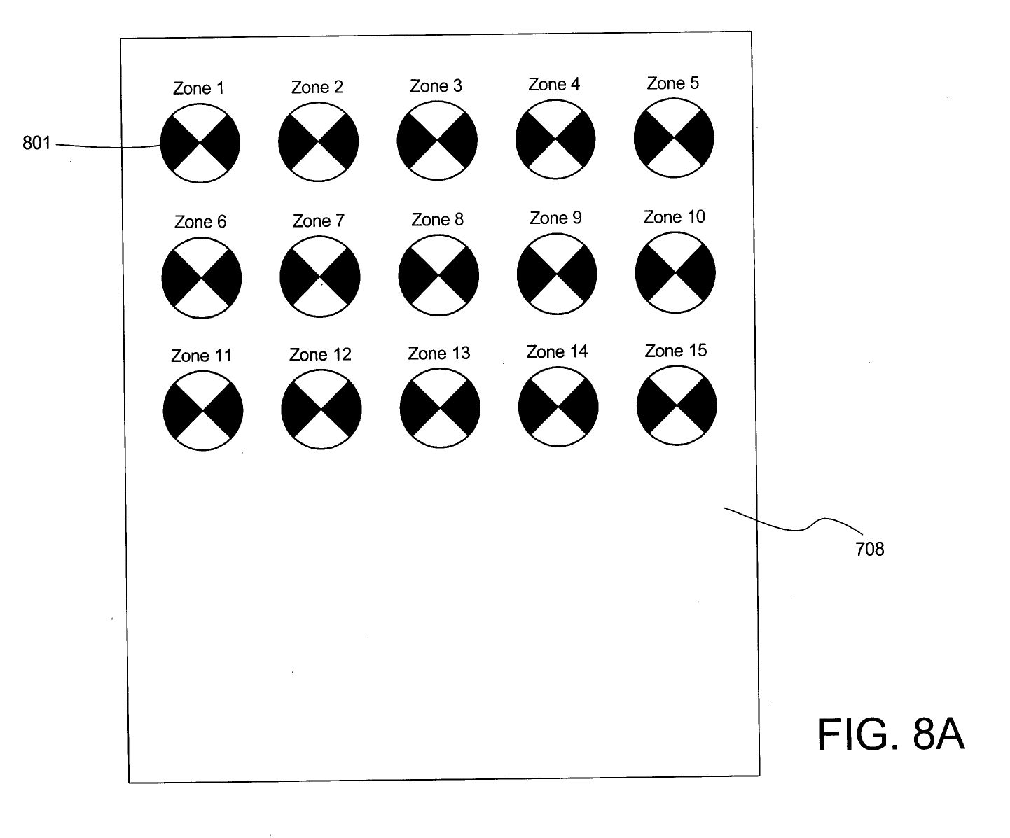

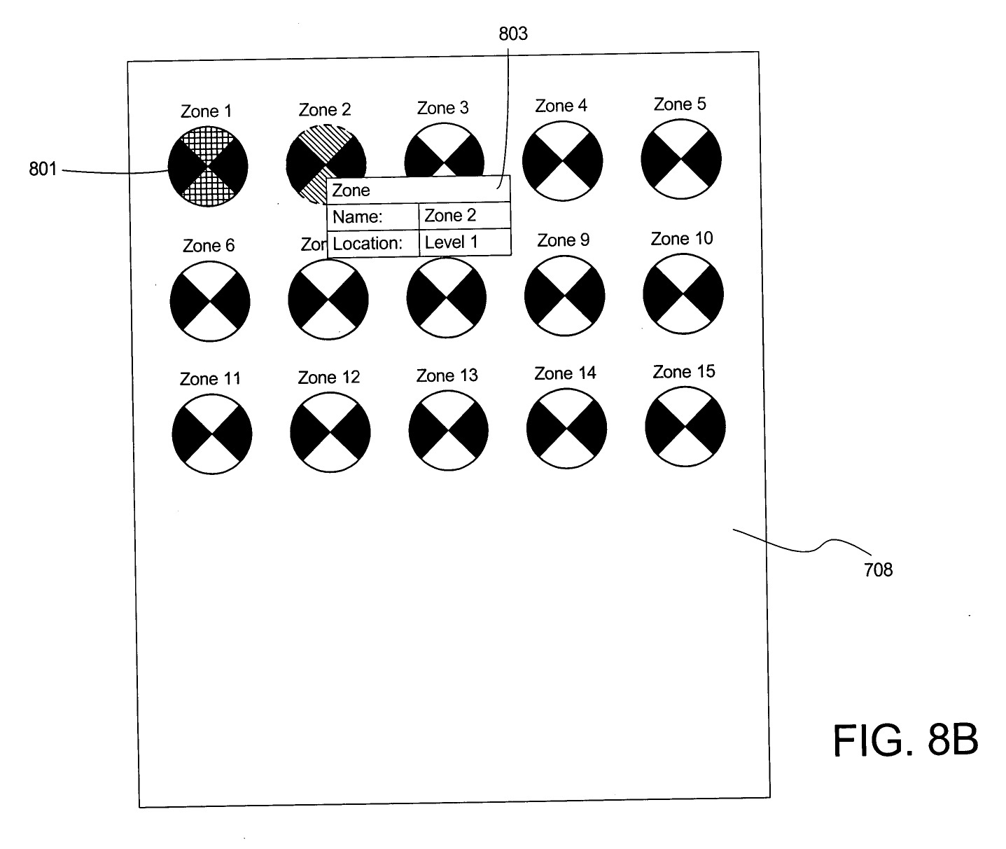

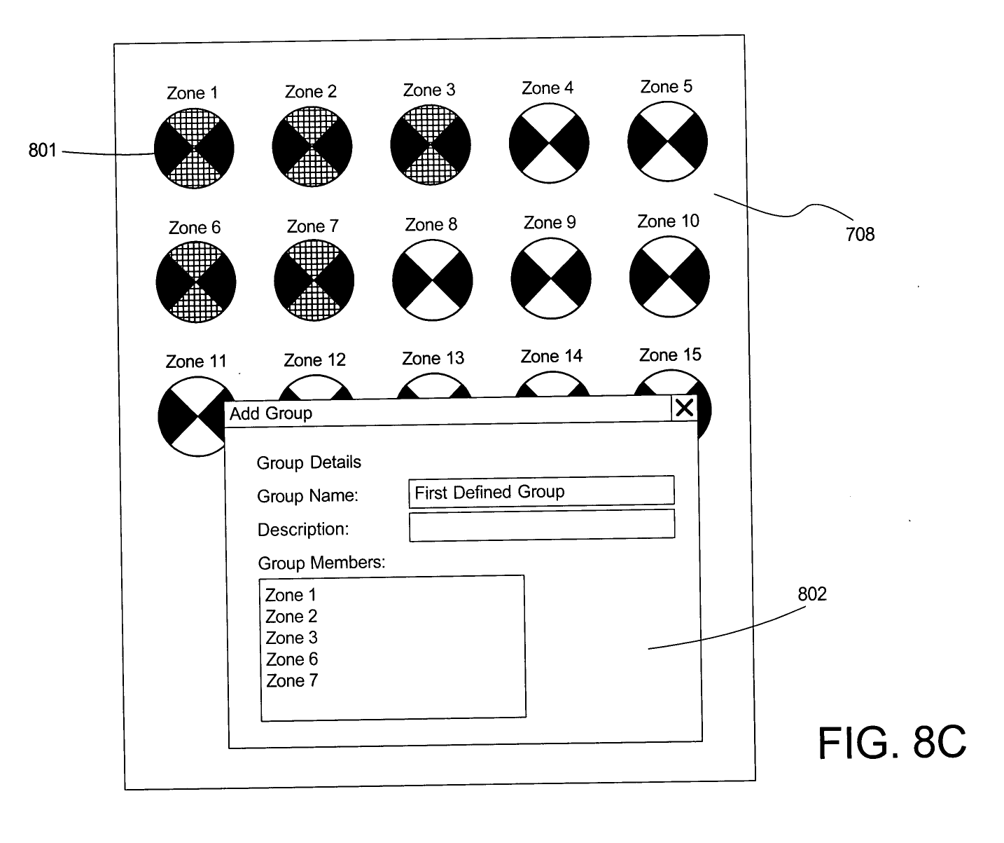

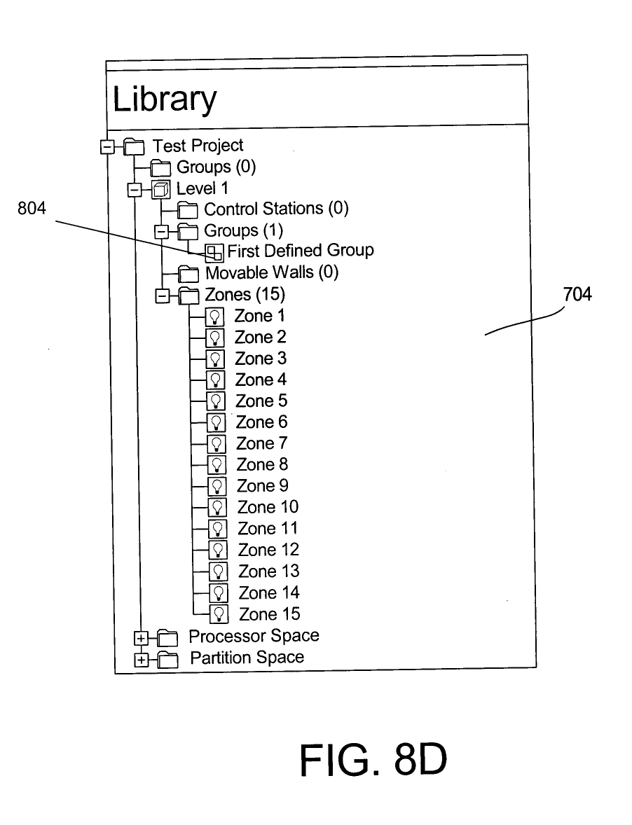

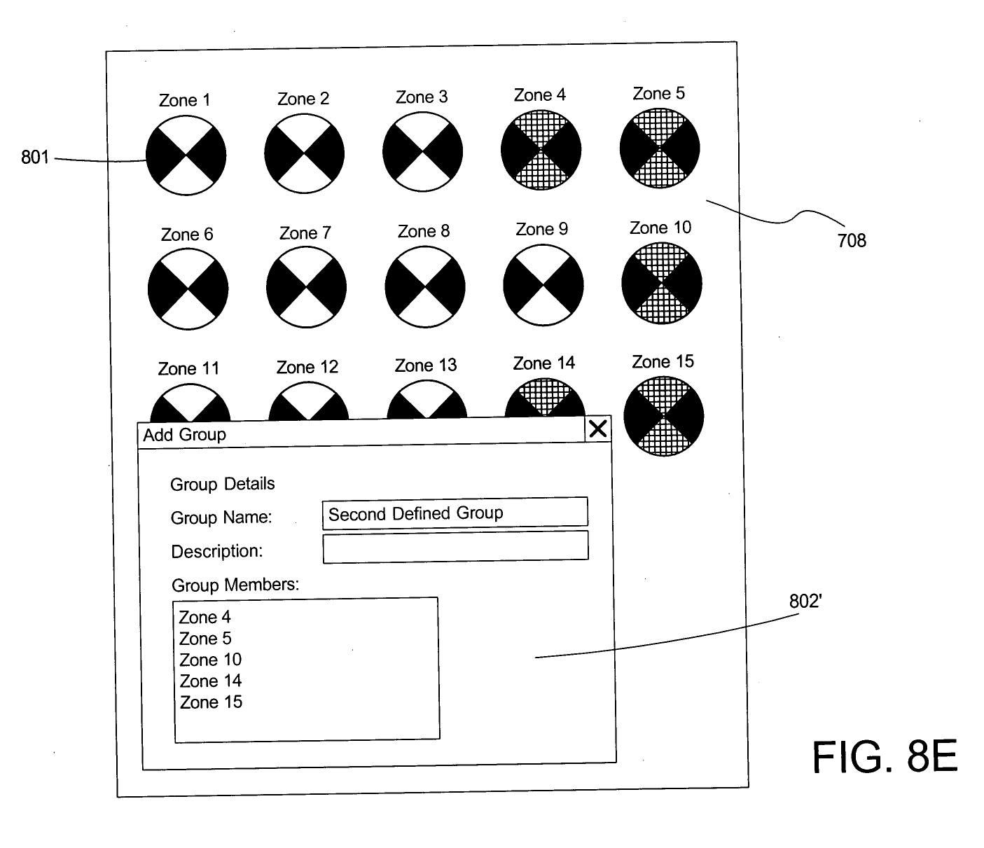

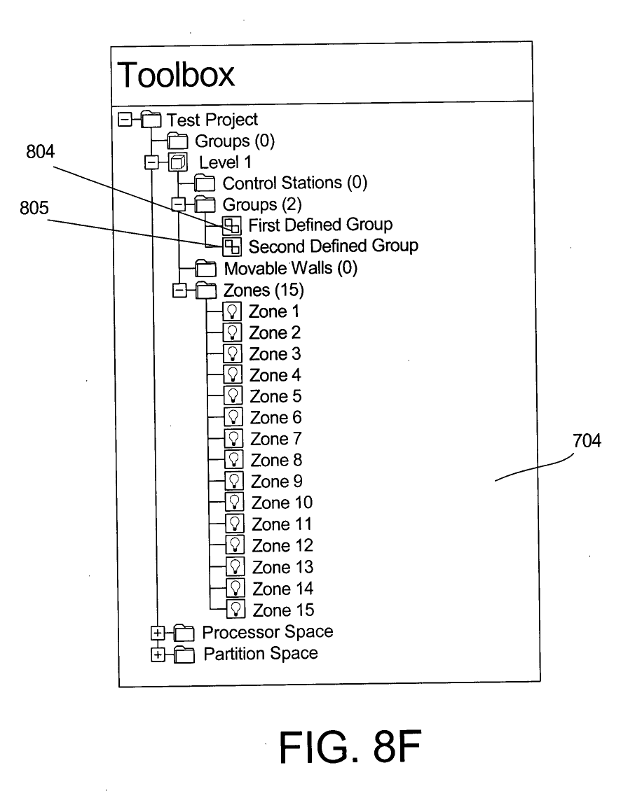

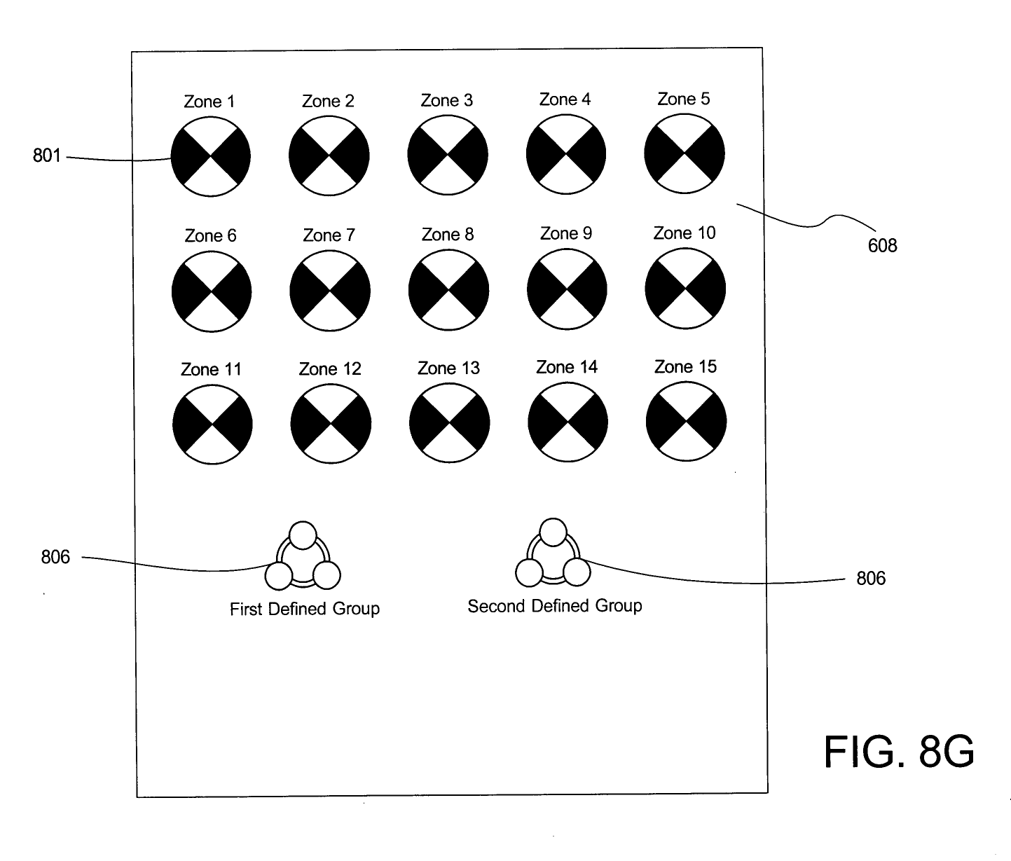

FIGS. 8A-8G show example panes of display screen 700 during varying stages in which the steps of grouping electrical/electronic devices 108 in accordance with a preferred embodiment of the present invention are executed.

As shown in FIG. 8A, fifteen graphic icons 801 representing lighting control points (i.e., zones) are added to main pane 708. Each of the fifteen graphic icons 801 representing zones was selected and dragged into main pane 708 from library pane 704. Using library pane 704, a user can identify particular zones to be monitored and/or controlled as a group.

Continuing with the present example, FIG. 8B shows main pane 708 and illustrates that zone 1 has been added to a group. This is effected by a user clicking on the graphic icon of zone 1 with a mouse. Preferably, zone 1 is indicated as being assigned to a group by the icon turning color, for example, to orange. Also as shown in FIG. 8B, when the user places the mouse pointer over the icon representing zone 2, the icon changes color (e.g., to green) which indicates that this symbol represents a valid object that can be added to the group. Also, dialog box 803 containing the name and location of the zone is displayed. Thus, by simply moving a selector over an icon in main pane 708 in draw module 306, a user can determine whether the icon in main pane 708 represents an object that supports grouping, as described herein.

Continuing with the examples shown in FIGS. 8A-8G, FIG. 8C illustrates main pain 708 with zones 1, 2, 3, 6 and 7 appearing in a different color than the other zones, thereby representing that zones 1, 2, 3, 6 and 7 have been added to a group. Also shown in FIG. 8C, dialog box 802 is displayed and can indicate which items have been added to the group after the user has completed adding items to the group. Preferably, users can modify group definitions, for example, by adding and removing items, as needed over time. In the example shown in FIG. 8C, users specify a name and description for the new group in dialog box 802, for example, for future reference.

FIG. 8D illustrates the library pane 704 of display screen 700 after the newly defined group, named “First Defined Group” has been created. After a group is created, the group is preferably represented in pane 704 for future use, such as to control the electrical/electronic devices included therein. In the example shown in FIG. 8D, group icon 804 (displayed in pane 704) represents the newly added group.

FIG. 8E shows display screen 800 while a user is defining a second group named “Second Defined Group.” In the example shown in FIG. 8E, the second group includes zones 4, 5, 10, 14 and 15. Dialog box 802′ indicates to the user the zones that are included in “Second Defined Group.”

FIG. 8F illustrates library pane 704 after “First Defined Group” and “Second Defined Group” have been defined. As shown in FIG. 8F, library pane 704 illustrates that both newly defined groups are available for use in accordance with the teachings herein. In the example shown in FIG. 8F, group icon 805 represents the second added group.

FIG. 8G illustrates graphic screen controls (i.e., icons) that have been dragged from pane 604 into main pane 608. In the example shown in FIG. 8G, group section 806 includes icons representing “First Defined Group” and “Second Defined Group” have been dragged from pane 604 and dropped into main pane 608. By dragging virtual representations of the groups (i.e., icons) from pane 604 into main pane 608, users will be able to control these groups of objects via a custom user interface provided, for example, over communication network 106 (FIG. 1).

Thus, in accordance with the present invention, draw module 306 enables users to develop custom user interfaces for controlling groups of electrical/electronic devices 108 substantially in real time, or, for example, in accordance with a particular schedule or in response to a condition. After the user interface is developed, preferably, by using the various modules described herein, the interface is presented to users over a communication network, for example, in a web browser display screen.

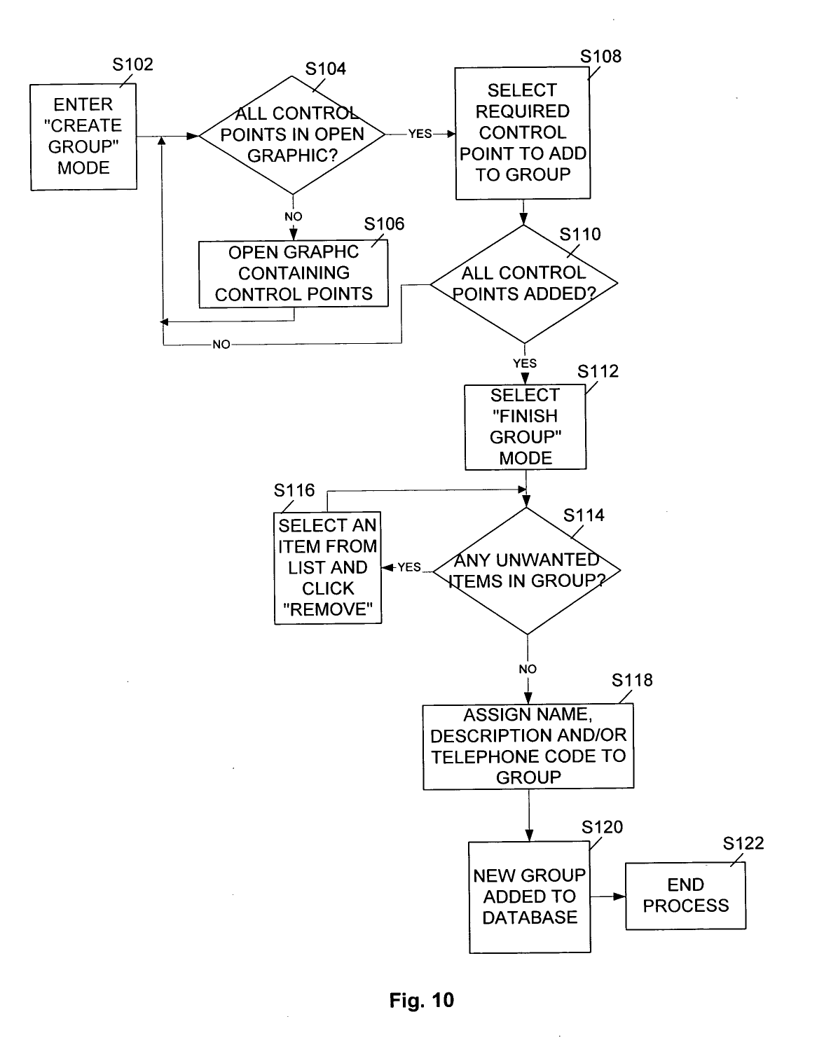

FIG. 10 is a flow chart illustrating steps associated with defining groups of electrical/electronic devices 108 in accordance with a preferred embodiment of the present invention.

In step S102, a user entering “create group” mode sets an internal state variable which represents that future actions relate to group creation functionality. In a preferred embodiment of the present invention, an internal array structure is initialized and used by information processor 102 to store contents and information of the group being defined. After group creation mode is selected, clicking on a control point, for example, in main pane 708, adds the control point to a group. In case “Create Group” mode is not initially selected, selecting an icon or symbol representing an electrical/electronic device 108 will display properties associated with device 108. Thus, in step S104, system 100 makes a determination whether an icon representing an electrical/electronic device 108 has been placed in main pane 608 and, if not, the process continues to step S106 and waits for the user to place the respective icon in main pane 608.

In a preferred embodiment of the present invention, tools associated with the user interface and described herein are stored and retrieved in a database through web services using XML over a hypertext transfer protocol (“HTTP”) communication session. Graphic icons representing electrical/electronic device groups 112 are stored in the database in a compressed format and are displayed to a user via run time module 308, for example, in web browser display screen 900. Preferably, during development of the user interface via draw module 306, graphic icons are decompressed and processed to add corresponding script files in order to effect control over groups 112.

Once an icon representing an electrical/electronic device 108 (described as a control point in FIG. 10) is placed in main pane 608, the user selects the icon to add the device 108 to a new group (step S108). At this point, an identifier and a type of the electrical/electronic device 108 is stored in the internal array structure, and a check for duplication is performed before the item is added to the array. Further, the icon representing the electrical/electronic device 108 changes color to indicate that the device 108 has been added to the group. Also, other instances of the same identifier and type in the graphic change color to show their inclusion in the group. For example, a user is able to drop a zone (for example zone 1) onto a graphic ten times, thereby defining and displaying ten zonel icons. The zonel icons are added to the group when they are selected, for example, by clicking on them with a mouse or other pointing device. The icons are displayed as being highlighted to represent that they have been associated with the group. In a preferred embodiment of the present invention, the graphic icons and various editing tools are provided as scalable vector graphics. The scalable vector graphics contain programming code that send commands for controlling electrical/electronic devices 108, and further receiving processing and displaying information for monitoring purposes.

After the icon representing electrical/electronic device 108 is added to a group, a determination is made whether additional devices 108 are to be added to the group (step S110). If not all devices 108 have been added to the group, then the process loops back to step S104. If all devices 108 have been added, then the process proceeds to step S112, and the user enters “Finish Group” mode to define the group. More particularly, in step S112, selecting “Finish Group” signals that the user has added all the items desired to the group. The user is preferably presented with a list of all the electrical/electronic devices 108 that have been added to the group, and the user is afforded an opportunity to remove individual items from the list (step S114). If, in step S114, the user decides to remove an unwanted electrical/electronic device 108 from the group, the process continues to step S116 and the user is presented with a list of items. The user preferably selects a particular device 108 to remove that device from the group. Thereafter, the process loops to step S114 and the user determines whether an additional electrical/electronic device 108 should be removed from the group. In step S114, once the user is satisfied with the contents of a group, the process continues to step S118 and the user is afforded an opportunity to assign a name and description (as described above) for describing and controlling the group. In step S120, the new group is added to a database for future use, and in step S122, the process ends.

Thus, in accordance with the example steps illustrated in FIG. 10, users can add electrical/electronic devices 108 to groups and enable control over the groups via custom user interfaces. A request to add a new group to the database is sent from draw module 306 using XML web services over a HTTP communication. If there are no problems, a message is preferably transmitted from the database indicating everything has been added successfully. If there were any errors, then a message indicating the error will be transmitted for the user.

In accordance with the present invention, creation of groups can span multiple graphics representing various electrical/electronic devices 108. As described above, items added to a group are preferably selected from graphics representing electrical/electronic devices 108 capable of being grouped and placed in main pane 708 in draw module 306. Preferably, graphics can be opened and utilized after the user has started creating a group. Also, a control point can control multiple logical and hardware types, including but not limited to shades, lighting fixtures, wall and control stations.

Furthermore, newly created groups can be accessed and used in design module 302 for programming purposes. By providing programming commands to operate on groups, real-time control of electrical/electronic devices 108 in a space or facility is effected.

Run Time Module

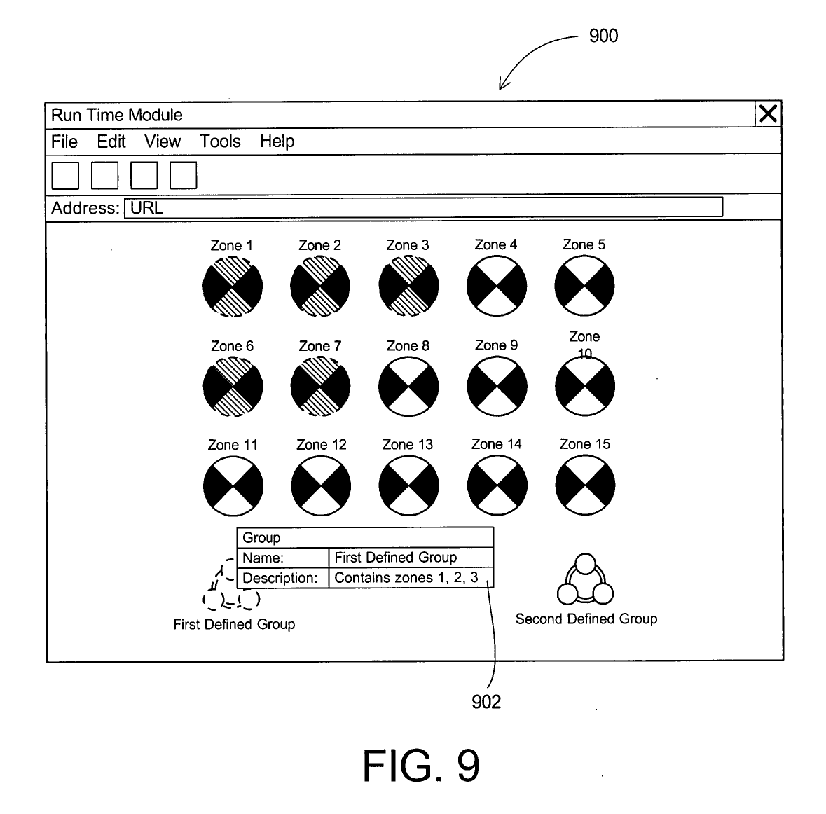

FIG. 9 shows an example display screen 900 that is provided to control a group of electrical/electronic devices 108 via run time module 308. In the example shown in FIG. 9, display screen 900 is provided in a web browser software application, enabling a user to control the system via the graphical interface displayed therein. This is accomplished, for example, by saving the groups defined in draw module 306 (described with reference to FIGS. 8A-8G) in a database which are, thereafter, referenced by information processor 102 to enable control over the groups of electrical/electronic devices.

In a preferred embodiment of the present invention, the icons representing “First Defined Group” and “Second Defined Group” provide information about each respective group when, for example, a mouse (or other pointing device) selector passes over the respective icon. For example and as illustrated in FIG. 9, a dialog box 902 containing the name of the group and a brief description of the group is automatically provided near the graphic icon representing the group, “First Defined Group,” when the mouse selector passes over (or near) the icon representing the group. Also as shown in FIG. 9, by moving the mouse selector over or near the group icon, the zones included in the group (e.g., zones 1, 2, 3, 6 and 7) appear differently, such as by changing color. In this way, by simply moving a mouse selector over a group icon in a web browser display screen, the user is informed of the electrical/electronic devices 108 that are associated with the respective group. The user selects the icon representing a group in order to avail himself of options that will affect all of the objects defined in the group.

Thus, using standard web browser software, a user can control objects that were defined in design module 302 and grouped in draw module 306, remotely over a communication network, such as the Internet. For example, a user can control all stairwell lighting, all exterior lighting, all control station devices and all walls in partitionable spaces using standard web browser software.

In addition to web browser software applications, the present invention preferably is operative to enable users to control groups of objects using a touch tone telephone. For example, a user dials a telephone number to invoke a telephone interface. The user preferably enters a group code, presses the “#” symbol, and enters an action code to monitor and/or control electrical/electronic device groups 112. In this way, users are not required to use a computing device employing web browser software to control electrical/electronic device groups 112.

Example System

Features and advantages of the present invention are now further described by way of an example.

A new convention center is being constructed in a city. The convention center is designed with 400,000 square feet of space and a 30 foot high ceiling. The convention center features 35 meeting rooms having a total of 144,800 square foot of space. The center also includes a food court and a 230,000 square foot main exhibit hall for accommodating various events such as trade shows, expositions, concerts, lectures, or various civic events.

During construction of the convention center, thousands of electrical/electronic devices 108 are installed throughout the various spaces. For example, dozens of rows of lights are installed in the ceiling in the main exhibition hall, with one or more lights associated with a zone. Thus, thousands of potential zones are installed and associated with one or more lighting fixtures. Other electrical/electronic devices 108, such as DMX fixtures, ceiling fans, shades, audio devices or the like are also installed and associated with zones.

The electrical/electronic devices 108 that are installed in the new convention center are provided with hardware for remote control and access. For example, a control processor 107, NICs 109 and one or more converter boxes 502 are provided to enable communication with the electrical/electronic devices 108. Many of the thousands of electrical/electronic devices 108 in the convention center are provided with hardware such that individual digital addresses are assigned to the devices 108.

Using the modules provided by the present invention, a user operating design module 302 provides an appropriate user name and password, and defines virtual representations of spaces in the convention hall via navigation pane 602. For example, the main exhibit hall, the food court, a plurality of meeting rooms, a plurality of bathrooms, lobbies, stairwells, or the like are defined using navigation pane 602 in design module 302. After the user is satisfied with the spaces defined for the convention center, the user further adds representations of electrical/electronic devices 108 and associates each device with one or more zones.

Thereafter, the user accesses draw module 306 to define a user interface for controlling groups of zones in the convention center. Using pane 702, the user selects the main exhibition hall and imports an electronic architectural drawing of the exhibit hall, formatted as a JPEG, in the draw module 306. Using pane 704, the user drags specific zones representing one or more devices 108 installed in the main exhibit hall into main pane 708. The zones are placed in main pane 708 in the respective portions of the JPEG image that represent the areas of the main exhibit hall where the zones are located. Thus, an accurate representation of the main exhibit hall and the zones that are to be grouped in accordance with the present invention is provided.

One of the groups of zones to be defined by the user controls lights that are positioned over a stage when the main exhibit hall is used for a musical performance. Using a mouse, the user selects the zones in main pane 708 that are positioned directly over the area where the stage will be placed. After the zones are selected, the user saves the defined zone with a specific name, “Stage Lights Group.” Next, a second group of lights is defined by the user for all of the zones associated with lights that are not located over the stage area. Using a mouse, the user selects each zone in this area to include the zones in the second group and saves the second group with the name, “Lights Outside of Stage Group.” A third group is defined by the user that includes all of the zones in the Stage Lights Group and in the Lights Outside of Stage Group. The user saves this third group with the name, “All Lights in Main Exhibit Hall Group.”

After the three groups are defined, the user instructs the present invention to provide the groups as an interface that is provided on a web site and is operative to communicate with a database accessible by information processor 102. The interface enables access to the database substantially in real time, as operators of the web site use the interface to manipulate the groups of zones. After the user has completed compiling the new user interface, the interface is stored on information processor 102 and is accessible via a standard HTTP communication session.

Once construction of the convention center is complete, a musical performance to celebrate the opening of the convention center's main exhibit hall takes place. An operator of the user interface developed in accordance with the present invention establishes a communication session with information processor 102 and, using a standard web browser software application, controls the groups of lighting zones defined previously via the present invention. Prior to the performance, all of the lights in the main exhibit hall are turned on at 70% luminance, with respect to the total lighting capacity in the main exhibition hall.

Using the All Lights in Main Exhibit Hall Group, the operator lowers the lights defined in the group just prior to the start of the musical performance to 0% luminance. Thereafter, the operator selects the Stage Lights Group and illuminates the stage therewith. Selecting the Lights Outside of Stage Group, the operator illuminates the lighting fixtures associated therewith to illuminate the lights at 10% luminance. This provides some light outside of the stage area, for example, to prevent accidents, while providing enough of a contrast of light between the stage area and the rest of the main exhibit hall.

After the performance is complete, the operator selects the Stage Lights Group to lower the luminance of the lights in this group and selects the Lights Outside of Stage Group to increase the luminance of the lights associated therewith. Thus, the operator can restore the degree of luminance in the lighting hall prior to the musical performance.

Although the previous example regards lighting fixtures and groups of zones with which lighting fixtures are associated, as noted above, the present invention is applicable for many other purposes. Using schedule module 310, groups of electrical/electronic devices 108 defined in accordance with the present invention are scheduled to turn on or off at particular times. For example, at 5:00 p.m. on Friday afternoons, groups of lights turn off in areas where an expected number of people in those areas is low. Further, groups of zones associated with HVAC systems are also scheduled to turn off at 5:00 p.m. on Fridays. In this way, air conditioning systems in the summer and/or heating systems in the winter can be regulated in areas where the expected number of people varies depending upon the time of day, day of week, week of month, and so forth.

Furthermore, using security module 312, authorized users are defined to permit individuals access to the various modules and the web enabled interface by the present invention. In this way, if an unauthorized user tries to gain access to the modules and/or web enabled interface, for example, in order to control lights or other electrical/electronic devices 108, the security module 312 prevents access.

Conclusion

Thus, the present invention provides convenient tools for developing custom interfaces for controlling groups of electrical/electronic devices 108. As noted above, electrical/electronic devices 108 that are located far apart from each other or perform vastly different functions can be grouped to operate (or locked to prevent altering an operation) together.

Returning to the example above with respect to the new exhibition hall with many rows and columns of lights, the present invention solves the problem found in prior art systems by providing an intuitive interface for defining and controlling groups of electrical/electronic devices. By dragging icons representing zones, fixtures or other electrical/electronic devices into a portion of a display screen (e.g., main pane 608), a user can simply click once on the icons to add them to a group. Furthermore, convenient color coding is provided to alert a user of the status of an electrical/electronic device 108 (e.g., as grouped or capable of being grouped). Thereafter, the user interface provided by the present invention enables a user to easily and quickly identify groups by moving a selector (e.g., a mouse pointer) over an icon representing a group to reveal information, such as the name, description and associated devices 108, about the group. Thus, the present invention saves significant amounts of time and costs associated with defining, monitoring and controlling groups of electrical/electronic devices 108.

Although the present invention has been described in relation to particular embodiments thereof, many other variations and modifications and other uses will become apparent to those skilled in the art. It is preferred, therefore, that the present invention be limited not by the specific disclosure herein.

What is claimed is:

1. A system for graphically grouping a plurality of electrical devices, to control the devices as at least one device group, the system comprising:
an information processor operative to store a plurality of graphical objects, wherein each of the graphical objects represents a respective one of the plurality of electrical devices, and is operative to electrically control the respective electrical devices;
a draw module operative to display the plurality of graphical objects and to define the at least one device group in response to a user selection of at least one of the graphical objects; and
a run time module operative to electrically control the at least one device group in response to the user selection defining the at least one device group.

2. The system of claim 1, wherein the at least one device comprises a zone.

3. The system of claim 1, wherein each graphical object represents a zone, and wherein a zone comprises at least one device, and further wherein the at least one device group comprises at least one zone.

4. The system of claim 1, wherein the draw module is operative to modify the appearance of the at least one graphical object to indicate that the at least one device represented by the at least one graphical object is included in the device group.

5. The system of claim 1, wherein the run time module is further operative to control the device group as a function of each of the at least one selected graphical object controlling its at least one respective device.

6. The system of claim 1, wherein the draw module is further operative to display at least one of a navigation pane, a toolbox pane, a properties pane and a main pane.

7. The system of claim 1, further comprising a scheduling module operative to control the device group according to a predefined schedule.

8. A system for developing a user interface for graphically controlling a group of at least two devices, the system comprising:
a design module provided by an information processor and operative to represent a physical location and to represent the at least two devices installed in the physical location;
a draw module provided by the information processor and operative to logically associate the at least two devices with the group;
wherein at least one command is associated with the group and further wherein the at least two devices perform at least one respective function in response to the command; and
a run time module operative to generate the user interface from information provided by at least one of the design module and the draw module, and further operative to provide the user interface on a display, wherein the user interface is operative to control the group via the information processor.

9. The system of claim 8, wherein one of the at least two devices is an electrical device and the other of the at least two devices is an electronic device.

10. The system of claim 8, wherein the at least two devices represent zones.

11. The system of claim 8, wherein at least one of the design module and the draw module includes at least one of a navigation pane, a toolbox pane, a properties pane and a main pane.

12. The system of claim 11, wherein the draw module is further operative to display characteristics of the at least two devices in the toolbox pane.

13. The system of claim 11, wherein the draw module is further operative to display graphic representations of the at least two devices in the main pane.

14. The system of claim 13, wherein the draw module is further operative to associate the graphic representations with the group.

15. The system of claim 11, wherein the information processor displays a representation of the group in the main pane.

16. The system of claim 8, further comprising a control processor operative to forward the command transmitted from the information processor to at least one of the at least two devices.

17. The system of claim 8, further comprising a workstation operative to display the user interface, and further operative to transmit the command from the user interface to the information processor in response to a selection made by the user.

18. The system of claim 8, further comprising a control module operative to set a priority for at least one of the at least two devices.

19. The system of claim 8, further comprising a schedule module operative to issue the command according to a predefined schedule.

20. The system of claim 8, wherein the user interface indicates the at least two devices as being associated with the group.

21. A method for graphically grouping a plurality of electrical devices, to control the devices as at least one device group, the method comprising:
storing a plurality of graphical objects in a memory of an information processor, wherein each of the graphical objects represents a respective one of the plurality of electrical devices, and the information processor is operative to electrically control the electrical devices;
displaying the plurality of graphical objects;
defining the at least one device group in response to a user selection of at least one of the graphical objects; and
controlling the at least one device group in response to the user selection defining the at least one device group.

22. The method of claim 21, wherein the at least one device comprises a zone.

23. The method of claim 21, wherein each graphical object represents a zone, and wherein a zone comprises at least one device, and further wherein the at least one device group comprises at least one zone.

24. The method of claim 21, further comprising modifying the appearance of the at least one graphical object to indicate that the at least one device represented by the at least one graphical object is included in the device group.

25. The method of claim 21, further comprising displaying at least one of a navigation pane, a toolbox pane, a properties pane and a main pane.

26. The method of claim 21, further comprising controlling the device group according to a predefined schedule.

27. A method for providing a user interface for graphically controlling a group of at least two devices, the method comprising:
graphically representing a physical location in a display and graphically representing the at least two devices at the physical location;
associating the at least two devices with the group; and
providing a user interface that is operative to issue a command to the group and wherein the at least two devices perform at least one respective function in accordance with the command.

28. The method of claim 27, wherein one of the at least two devices is an electrical device and other of the at least two devices is an electronic device.

29. The method of claim 27, wherein the at least two devices represent zones.

30. The method of claim 27, further comprising displaying at least one of a navigation pane, a toolbox pane, a properties pane and a main pane.

31. The method of claim 30, further comprising displaying characteristics of the at least two devices in the toolbox pane.

32. The method of claim 30, further comprising displaying graphic representations of the at least two devices in the main pane.

33. The method of claim 32, further comprising associating the graphic representations with the group.

34. The method of claim 30, further comprising displaying a representation of the group in the main pane.

35. The method of claim 27, further comprising forwarding the command to at least one of the at least two devices.

36. The method of claim 27, further comprising displaying the user interface over a communication network.

37. The method of claim 36, wherein the communication network is the Internet.

38. The method of claim 27, further comprising defining a priority for at least one of the at least two devices.

39. The method of claim 27, further comprising issuing the command according to a predefined schedule.
